(19) United States
(12) Patent Application Publication
(10) Pub. No.: US 2010/0085123 A1
(43) Pub. Date: Apr. 8, 2010

(54) INJECTION-LOCKED CLOCK MULTIPLIER

(75) Inventors: Yohan U. Frans, Sunnyvale, CA (US); Hae-Chang Lee, Los Altos, CA (US); Brian S. Leibowitz, San Francisco, CA (US); Jaeha Kim, Los Altos, CA (US)

Correspondence Address: PVF -- RAMBUS, INC.;c/o PARK, VAUGHAN & FLEMING, LLP, 2820 FIFTH STREET, DAVIS, CA, 95618-7759, US

(73) Assignee: RAMBUS INC., Los Altos, CA (US)

(21) Appl. No.: 12/577,027

(22) Filed: Oct. 9, 2009

(30) Foreign Application Priority Data
Apr. 22, 2008 (US) PCT/US2008/061118

(51) Int. Cl. H03L 7/24

(52) U.S. Cl. 331/47

(57) ABSTRACT

Embodiments of a clock circuit are described. This clock circuit includes an oscillator, which includes a resonance circuit having a resonance frequency, that outputs a first clock signal having a first frequency. Furthermore, a digital controller is coupled to the oscillator. This digital controller modifies the resonance frequency of the oscillator during a first mode of operation of the clock circuit, and the modifying is ceased during a second mode of operation of the clock circuit. In addition, on injection circuit is coupled to the oscillator. This injection circuit provides a second clock signal having a second frequency to the oscillator. Note that the second clock signal injection locks a phase and/or the first frequency of the first clock signal. Also note that a ratio of the first frequency to the second frequency is greater than or equal to one.

### FIELD OF INVENTION

The present embodiments relate to techniques for generating clock signals. More specifically, the present embodiments relate to circuits and methods for injection-locking oscillators.

### BACKGROUND

Advances in semiconductor process technology have made it possible for semiconductor devices to perform increasingly complicated functions at higher processing speeds. Unfortunately, the capabilities of energy-storage components (such as batteries) have not increased at the same rate. Consequently, power consumption is an increasingly important consideration in the design of circuits and devices.

Many existing devices address this problem by using power-management techniques. For example, circuits may be switched from an active mode of operation to a low-power or standby mode of operation when parts or all of the circuits are not being used. Note that power may be conserved in the standby mode of operation by turning off or disabling components and sub-circuits in these circuits.

However, turning off clock circuits in many devices may degrade performance because these clock circuits often have slow settling times or high latency when switching from a standby mode to an active mode of operation. This latency often precludes the clock circuits from being turned off, which prevents devices containing such circuits from taking advantage of power-management techniques.

Hence, what is needed is a clock circuit and a technique that overcomes the problems listed above.

### BRIEF DESCRIPTION OF THE FIGURES

FIG. 1A is a block diagram illustrating an embodiment of a clock circuit.

FIG. 1B is a block diagram illustrating an embodiment of a clock circuit.

FIG. 2A is a timing diagram illustrating an embodiment of clock signals showing the effect of injection locking.

FIG. 2B is a timing diagram illustrating an embodiment of clock signals showing the effect of injection locking.

FIG. 3 is a timing diagram illustrating an embodiment of clock signals and pulse waveforms.

FIG. 4A is a block diagram illustrating an embodiment of a pulse-generating circuit.

FIG. 4B is a block diagram illustrating an embodiment of a pulse-generating circuit.

FIG. 5 is a flow chart illustrating an embodiment of a process for generating a clock signal using a digital controller and injection-locking circuit.

FIG. 6 is a flow chart illustrating an embodiment of a process for generating a clock signal using a stored resonance value.

FIG. 7A is a graph illustrating an embodiment of clock signals.

FIG. 7B is a graph illustrating an embodiment of clock signals.

FIG. 8A is a graph illustrating an embodiment of periodic jitter as a function of the deviation from a target frequency.

FIG. 8B is a graph illustrating an embodiment of static-phase offset as a function of the deviation from a target frequency.

Note that like reference numerals refer to corresponding parts throughout the drawings.

### DETAILED DESCRIPTION

The following description is presented to enable any person skilled in the art to make and use the disclosed embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present description. Thus, the present description is not intended to be limited to the embodiments shown, but is to be accorded the widest scope consistent with the principles and features disclosed herein.

Embodiments of a clock circuit, an integrated circuit, and a technique for generating clock signals are described. This clock circuit includes an oscillator, which includes a resonance circuit having a resonance frequency, that outputs a first clock signal having a first frequency (such as a first fundamental frequency of a square wave). Furthermore, a digital controller is coupled to the oscillator. This digital controller modifies the resonance frequency of the oscillator during a first mode of operation of the clock circuit, and the modifying is ceased or disabled during a second mode of operation of the clock circuit. In addition, an injection circuit is coupled to the oscillator. This injection circuit may receive a third clock signal (such as a reference clock signal) and/or provides a second clock signal having a second frequency (such as a second fundamental frequency) to the oscillator. Note that the second clock signal injection locks the phase and/or the first fundamental frequency of the first clock signal. Also note that a ratio of the first fundamental frequency to the second fundamental frequency is greater than or equal to one. Therefore, in some embodiments the clock circuit is used as a clock multiplier to generate a system clock signal (i.e., the first clock signal) from a reference clock signal.

In some embodiments, the ratio is an integer. Furthermore, in some embodiments the injection circuit includes a pulse circuit that receives the third clock signal and/or provides the second clock signal to the oscillator, where the second clock signal includes pulses having a time spacing corresponding to the second fundamental frequency.

In some embodiments, the digital controller adjusts or sets the resonance frequency of the oscillator. For example, the digital controller may determine a frequency and/or a phase difference between a first signal corresponding to the first clock signal and a second signal corresponding to the second clock signal. Note that the adjustment or setting may be based on the frequency difference. Furthermore, in some embodiments the resonance circuit includes an inductor and a capacitor, and the digital controller modifies a capacitance of the capacitor. In some embodiments, the capacitor includes a switched-capacitor circuit and/or a digitally controlled varactor.

In some embodiments, the oscillator is coupled to a filter (such as a band-pass filter). For example, the filter may include a resonant-clock-distribution network.

In some embodiments, the clock circuit includes a regeneration circuit coupled to the resonance circuit, where the regeneration circuit restores energy in the oscillator. Furthermore, in some embodiments the regeneration circuit may have a negative transconductance. For example, the regeneration circuit may include: one or more current sources and a cross-coupled differential transistor pair, and/or a pair of cross-coupled inverters.

In some embodiments, the first mode of operation is an initialization or calibration mode of operation, and the second mode of operation is an active mode of operation. Furthermore, the clock circuit may operate in a third or standby mode of operation. During the third mode of operation, the regeneration circuit, the digital controller, and the injection circuit are disabled. Moreover, when transitioning from the third mode of operation to the second mode of operation, the digital controller is enabled and sets the resonance frequency based on a stored value (such as a stored capacitance setting of the capacitor). Then, the injection circuit and the regeneration circuit are enabled, and the injection circuit provides the second clock signal. Note that a settling time of the first clock signal during the second mode of operation (or when transitioning from the third mode of operation to the second mode of operation) is less than a pre-determined multiple (such as five) of the inverse of the second fundamental frequency (i.e., a period of the second clock signal).

Another embodiment provides a method for generating a clock signal. During this method, the regeneration circuit drives the resonance circuit, which results in the oscillator outputting the first clock signal. Note that this regeneration circuit may restore energy in the oscillator. Furthermore, the digital controller modifies the resonance frequency of the resonance circuit. After this modifying, the first fundamental frequency is within a predetermined range of frequencies around a target frequency. In addition, after the modifying the injection circuit couples the second clock signal to the oscillator, thereby injection locking the first fundamental frequency of the oscillator to the target frequency.

Thus, by injection locking the oscillator using an open-loop controller (such as the injection circuit), the clock circuit may have a fast settling time. This fast settling time may facilitate switching of the clock circuit to and from the active mode of operation and the standby mode of operation, thereby enabling the clock circuit to take advantage of power-management techniques and thus reducing power consumption in circuits, integrated circuits, devices, and/or systems that include an embodiment of the clock circuit.

Embodiments of the clock circuit may be used in a wide variety of applications, including: microprocessors, source-synchronous input/output circuits, and/or input/output circuits that include clock-recovery circuits. In some embodiments, an embodiment of the clock circuit is included in circuits, devices, and/or systems that include distributed clock signals or mesochronous clock signals (such as XDR™ DRAM). Furthermore, in some embodiments the clock circuit is included in: a memory controller, a solid-state memory component (for example, a non-volatile memory, such as dual-data-rate DRAM), parallel or serial links (such as PCI Express), and/or portable electronic devices (such as cellular telephones, personal digital assistants, etc.). And in some embodiments, the clock circuit is used in or with a burst-mode receiver, in which the clock signal generated by the clock circuit is synchronized with a given stream of bits in a given data packet using a preamble associated with the given data packet.

Note that in contrast with multipliers that include or are based on a phase-locked loop, in some embodiments the multiplier in the clock circuit may not use a feedback loop and/or a loop filter in the active mode of operation once the fundamental frequency of the first clock signal is locked to the target frequency. This simplification of the clock circuit may: reduce power consumption during the active mode of operation, reduce settling time upon starting or restarting the clock circuit, and/or reduce or eliminate stability problems associated with clock circuits.

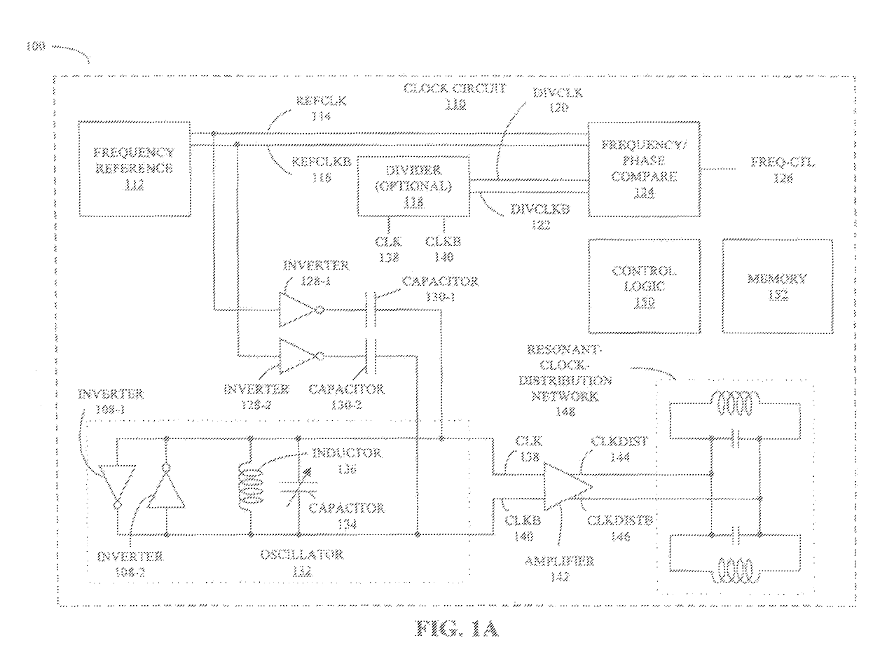

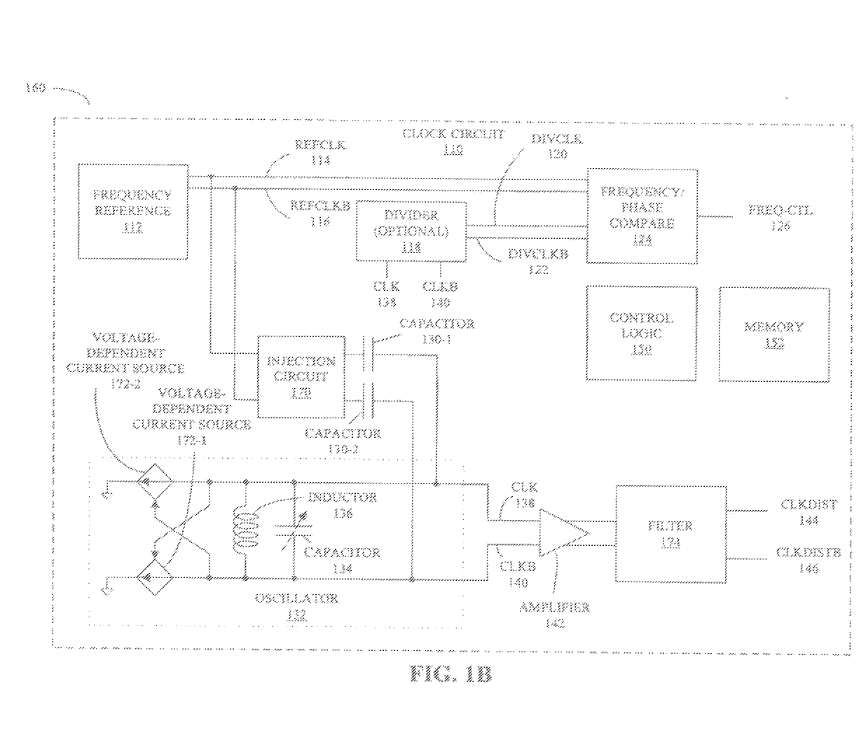

We now describe embodiments of a clock circuit. FIG. 1A presents a block diagram illustrating embodiment 100 of a clock circuit 110. In this circuit, a frequency reference 112 provides a reference clock signal (refclk) 114 and/or an out-of-phase reference clock signal (refclkb) 116. Note that in some embodiments refclkb 116 is approximately 180° out of phase with respect to refclk 114.

In an exemplary embodiment, frequency reference 112 includes a crystal oscillator or a reference oscillator. Furthermore, in some embodiments frequency reference 112 includes a phase-locked loop (PLL) and/or a delay-locked loop (DLL). And in some embodiments, refclk 114 and/or refclkb 116 are generated by interpolating between one or more phasor signals.

In the clock circuit 110, refclk 114 and/or refclkb 116 are used to injection lock a phase and/or a frequency of oscillator 132. In particular, inverters 128 are used to couple these clock signals to the oscillator 132, which includes a resonance circuit. In an exemplary embodiment, the resonance circuit includes a capacitor 134 and an inductor 136 in parallel with each other. A resonance frequency of the resonance circuit may be set or adjusted (or more generally, modified), for example, by changing the capacitance of the capacitor 134 and/or the inductance of the inductor 136. Note that setting the resonance frequency may involve selection from a set of discrete values, while adjusting may involve varying a continuous value. In the clock circuit 110, the capacitance of capacitor 134 is adjustable. As discussed further below, this capacitance may be modified based on frequency control signal (freq-ctrl) 126, which is output from frequency/phase comparator 124.

Note that capacitor 134 and/or inductor 136 may be implemented using on-chip (integrated) and/or off-chip (discrete) components. For example, inductor 136 may include a spiral inductor and/or a transmission line. In addition, capacitor 134 may include: a switched-capacitor circuit, a reverse biased p-n junction, and/or a varactor, which each have a voltage-controlled capacitance.

Furthermore, note that in some embodiments refclk 114 and/or refclkb 116 are coupled to the oscillator 132 via capacitors 130. These coupling capacitors and capacitor 134 may form a capacitance divider. In an exemplary embodiment, this divider reduces the amplitude of refclk 114 and/or refclkb 116 injected into the oscillator 132 by a factor of approximately 4.

While capacitance 134 and inductor 136 are each illustrated as having reactance, in practice both of these components also have resistance, i.e., energy loss. An energy restoring device or regeneration circuit may be used to maintain the resonant signals in the oscillator 132. For example, the oscillator 132 may include cross-coupled inverters 108. More generally, the resonance circuit in the oscillator 132 may be driven by one or more circuits or components having a negative transconductance.

The oscillator 132 may be used to generate output clock signal (clk) 138 and/or an out-of-phase output clock signal (clkb) 140. Note that in some embodiments clkb 140 is approximately 180° out of phase with respect to clk 138. Furthermore, clk 138 and/or clkb 140 may be coupled to an output buffer or amplifier 142.

Amplifier 142 provides a distribution clock signal (clkdist) 144 and/or out-of-phase distribution clock signal (clkdistb) 146 to a resonant-clock-distribution network 148, which may help save power by re-circulating some of the energy output by amplifier 142. Note that in some embodiments clkdistb 146 is approximately 180° out of phase with respect to clkdist 144.

As discussed further below, resonant-clock-distribution network 148 may band limit clk 138 and/or clkb 140, thereby reducing or eliminating periodic jitter (which is associated with the injection-locked oscillator 132) in clkdist 144 and/or clkdistb 146. For example, resonant-clock-distribution network 148 may have a quality factor (Q) of 4, and may have band-pass transfer function.

As noted previously, the resonance frequency of the oscillator 132 may be modified, for example, based on freq-ctrl 126 output from frequency/phase comparator 124. As illustrated in clock circuit 110, optional divider 118 may divide clk 138 and/or clkb 140 (or a buffered version of these signals) and provide divclk 120 and divclkb 122. Refclk 114 and/or refclkb 116 and the outputs from the optional divider 118 are coupled to frequency/phase comparator 124, which determines freq-ctrl 126. For example, frequency/phase comparator 124 generates freq-ctrl 126 representing a frequency/phase difference between divclk 120 and refclk 114. Note that in some embodiments frequency/phase comparator 124 includes a digital frequency counter. Thus, in some embodiments the oscillator 132 is digitally controlled. This digital control may be used to adjust the resonance frequency of the oscillator 132 close to a target frequency, such as a specific multiple of the frequency of refclk 114.

While this process for setting or adjusting the resonance frequency of the oscillator 132 may be time consuming, it may only be performed once, as needed, and/or periodically (for example, during a calibration mode of operation of the clock circuit 110). In exemplary embodiments, the resonance frequency is modified when the clock circuit 110 is turned on for the first time, or if the resonance frequency deviates sufficiently from a target frequency (which may be determined by control logic 150, which may implement a digital controller, such as a state machine or an application-specific integrated circuit). Therefore, in some embodiments the resonance frequency is modified at least one time after a time interval has elapsed since a previous setting or adjustment. However, in other embodiments the resonance frequency is periodically modified.

Once the setting or adjustment has been determined at least a first time, revision or updates to freq-ctrl 126 by frequency/phase comparator 124 may be discontinued. Thus, frequency/phase comparator 124 may be disabled or may output a static value of freq-ctrl 126. Note that, in addition to saving power during an active mode of operation of the clock circuit 110, the injection-locking of the oscillator 132 is thus open loop, i.e., refclk 114 and/or refclkb 116 provide open-loop control of the oscillator 132. As discussed further below, this open-loop control avoids the usual tradeoff between the bandwidth of a loop filter in a clock circuit (for example, in a phase-locked loop) and the latency or settling time of a clock circuit. Therefore, clock circuit 110 has a reduced latency or settling time, which facilitates control logic 150 routinely switching clock circuit 110 to and from the active mode of operation and a standby mode of operation (thereby reducing power consumption in circuits and/or devices that include the clock circuit 110).

FIG. 1B presents a block diagram illustrating embodiment 160 of a clock circuit 110, which generalizes some of the components and functionality of embodiment 100 (FIG. 1A). In particular, injection circuit 170 is used to couple refclk 114 and/or refclkb 116 to the oscillator 132, and a cross-coupled differential transistor pair (or voltage-dependent current sources) 172 are used to restore energy in the oscillator 132. Furthermore, amplifier 142 may be coupled to a filter 174, which provides clkdist 144 and/or clkdistb 146. This filter may band limit clk 138 and/or clkb 140, thereby reducing or eliminating periodic jitter (which is associated with the injection-locked oscillator 132) in clkdist 144 and/or clkdistb 146. In some embodiments, filter 174 is a band-pass filter.

Note that clock circuit 110 in embodiments 100 (FIG. 1A) and/or 160 may include fewer components or additional components. For example, outputs from the clock circuit 110 may be coupled to additional clock circuits to produce one or more additional clock signals. Moreover, in some embodiments determination of freq-ctrl 126 is performed at least partially in software. In some embodiments, a phase and/or a frequency of the oscillator 132 are injection locked using one clock signal (such as refclk 114), and the oscillator 132 outputs one clock signal (such as clk 138). Furthermore, two or more components may be combined into a single component, and the position of one or more components may be changed. In some embodiments, the clock circuit 110 is included in an integrated circuit on a semiconductor die.

We now further discuss operation of the clock circuit 110 using embodiment 100 in FIG. 1A as an illustration. When the clock circuit 110 is turned on for the first time (or during the calibration mode of operation), inverters 128 (or the injection circuit 170 in FIG. 1B), and amplifier 142 are disabled. Then, cross-coupled inverters 108 (or current sources 172 in FIG. 1B) are turned on and the oscillator 132 self resonates. A frequency feedback loop provided by a digital controller (including frequency/phase comparator 124) may be swept until the adjustable capacitor 134 has a capacitance that results in a resonance frequency which is close to the target frequency. For example, a simple closed loop (for example, using a frequency counter) may be used to determine the capacitance of the capacitor that provides resonance close to the target frequency. This initial or coarse adjustment may tune the oscillator 132 to within several thousand ppm (or 0.1-0.2% of the target frequency) while the injection-locking signal(s) are disabled. Furthermore, a digital value corresponding to the capacitance may be stored so that it can be used later to provide a quick wake up time when the clock circuit 110 is turned on or switches from the standby modes of operation to the active mode of operation.

Next, the digital controller keeps the adjustable capacitor 134 fixed at the previously determined capacitance, and inverters 128 (or the injection circuit 170 in FIG. 1B) are enabled, thereby coupling refclk 114 and/or refclkb 116 to the oscillator 132 and aligning the phase and pulling-in the frequency of clk 138 and/or clkb 140 (which occurs quickly). This injection circuit locks the fundamental frequency of clk 138 and/or clkb 140 to the target frequency. In particular, the injection locking changes this fundamental frequency from the resonance frequency of the resonance circuit to the target frequency. Note that the fundamental frequency of clk 138 and/or clkb 140 after injection locking may be an integer multiple M of the fundamental frequency of refclk 114 and/or refclkb 116, i.e., a ratio of the fundamental frequency of clk 138 and/or clkb 140 to the fundamental frequency of refclk 114 and/or refclkb 116 may be greater than or equal to 1 (which is sometimes referred to as sub-harmonic injection locking). Thus, the clock circuit 110 may function as a clock multiplier. In an exemplary embodiment, M is 5.

Note that in some embodiments the phase alignment and frequency pull-in range provided by the injection-locking is greater than a drift of the resonance frequency of oscillator 132, and more generally, of the clock circuit 110. In an exemplary embodiment, the drift of the resonance frequency of oscillator 132 may include a temperature-dependent frequency drift of 1.6% over a temperature range of 100 C, and a voltage-dependent frequency drift of 0.1% over a voltage range of 100 mV, while the frequency pull-in range of the injection-locking may be greater than 2%.

As noted previously, prior to switching to a standby mode of operation, a frequency control setting (such as a digital word) corresponding to freq-ctrl 126 is stored, for example, in memory 152. Then, during the standby mode of operation, components in the clock circuit 110 may be turned off. However, in some embodiments frequency reference 112 is left on. Nonetheless, the ability to turn off most or all of the components in the clock circuit 110 reduces the power consumption during the standby mode of operation.

When switching from the standby mode of operation to the active mode of operation, inverters 128 (or the injection circuit 170 in FIG. 1B) and/or frequency reference 112 are turned on. For example, a control signal from control logic 150 may turn on one or more of these components. Alternatively, in some embodiments the digital word is saved as an output state of frequency/phase comparator 124, which remains available while consuming negligible power.

In addition, the stored frequency control setting of the oscillator 132 (such as a value of the capacitance of the capacitor 134) is restored. Then, the cross-coupled inverters 108 (or the current sources 172 in FIG. 1B) are turned on. Concurrently or subsequently, the amplifier 142 is turned on. For example, when the oscillation of the oscillator 132 starts to grow and reaches a sustainable level the amplifier 142 will amplify or couple signals to the resonant-clock-distribution network 148 (or the filter 174 in FIG. 1B).

Note that the use of the stored frequency control setting eliminates the use of a frequency loop to modify the oscillator 132 during the transition to the active mode of operation. Consequently, the oscillator 132 may injection locked using open-loop control (i.e., without feedback) except during the calibration mode of operation. This technique results in a reduced latency or a fast setting time of the clock circuit 110. For example, if M equals 5, the latency may be less than 5 periods of refclk 114, or 25 periods of clk 138.

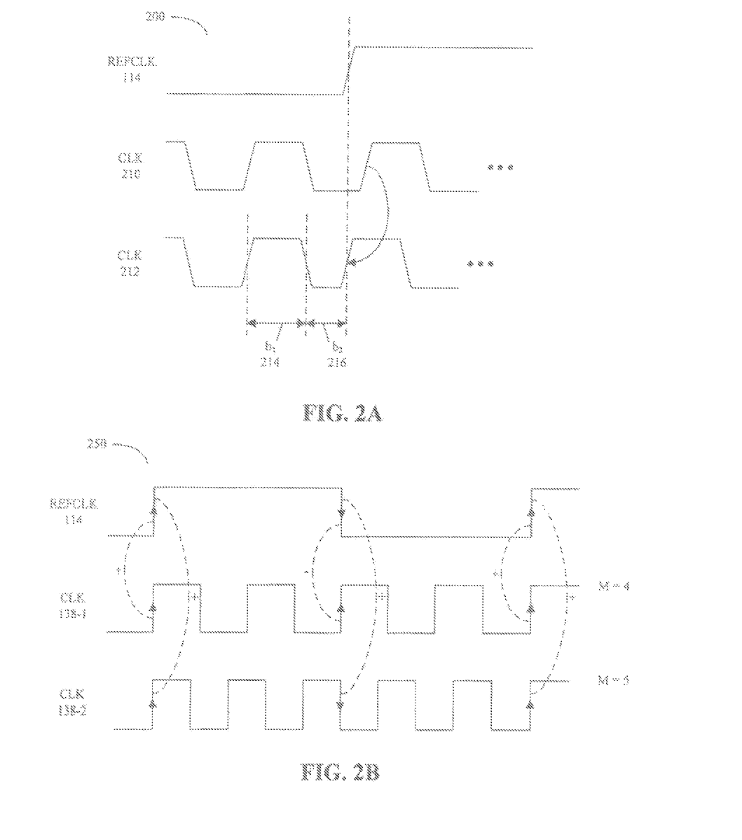

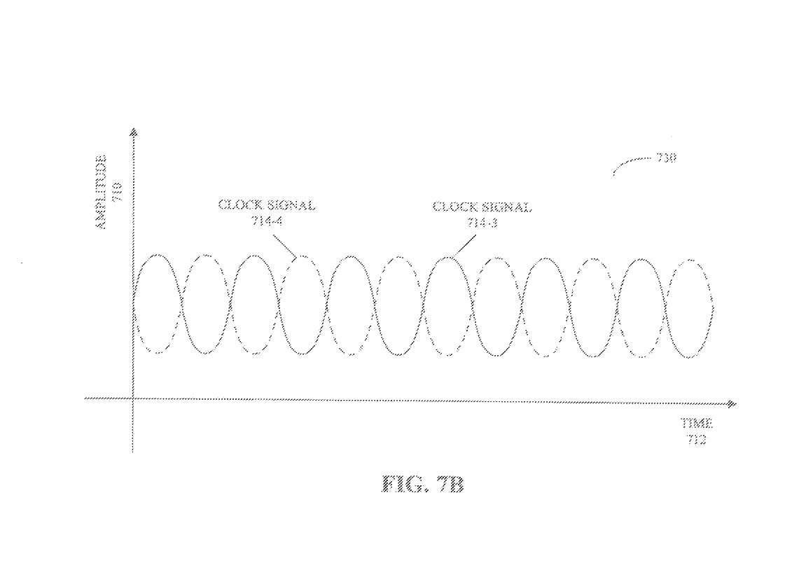

We now discuss injection locking in more detail. FIG. 2A presents a timing diagram illustrating an embodiment 200 of periodic clock signals each having a fundamental frequency. Note that without the injection-locking signal, edges or transitions in clk 210 (such as clk 138 in FIG. 1A) may be out of phase relative to edges or transitions in refclk 114. When this injection locking signal (i.e., reflck 114) is added, energy is provided to the oscillator 132 (FIGS. 1A and 1B) to change or pull-in edges of clk 212 (and in particular, every M^{th} edge of clk 212), as indicated by the curved arrow. This advances the phase of clk 212 to match the phase of refclk 114. However, this modification modulates a first portion of the period (b₂) 216 relative to a second portion of the period (b₁) 214 such that these portions are different even though the average period is correct. This modulation results in periodic jitter in clk 212, which is discussed further below with reference to FIGS. 7A and 7B.

Note that if refclk 114 contains substantially equally spaced rising and falling edges, and both are injected into the oscillator 132 with substantially equal strength, then the effect of injection locking cancels out on alternative bit times when M is even. This is illustrated in FIG. 2B, which presents a timing diagram of an embodiment 250 of clock signals that shows the effect of injection locking. For odd values of M (such an M of 5), the effect of the injection locking of clk 138-2 by refclk 114 is reinforced at each edge in refclk 114, because the transitions in refclk 114 always align with the same transition directions in clk 138-2. However, for even values of M (such an M of 4), the effect of the injection locking of clk 138-1 by refclk 114 is cancelled at alternate edges in refclk 114.

Note that while embodiments 200 and 250 illustrate the clock signals as square waves, in some embodiments other clock patterns are used, such as triangle waves and/or sine waves. More generally, the clock patterns are a weighted superposition of sine waves and/or cosine waves.

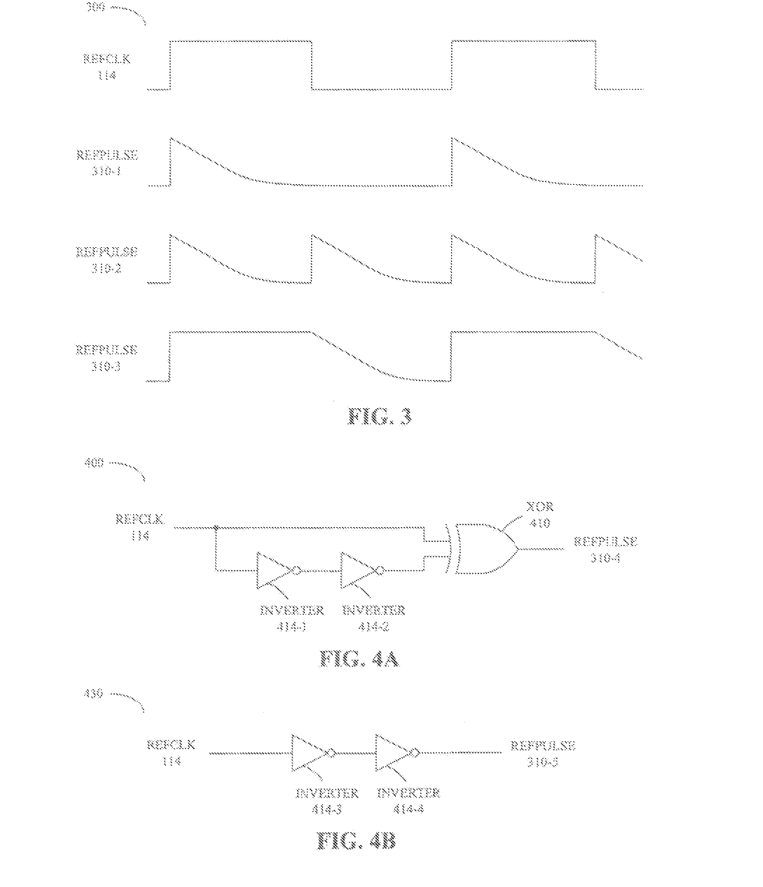

In some embodiments, clock circuit 110 (FIGS. 1A and 1B) outputs clk 138 (FIGS. 1A and 1B) having a fundamental frequency that is an even integer multiple M of the fundamental frequency of refclk 114 (FIGS. 1A and 1B) by changing the symmetry at refclk 114, refclkb 116, and/or the injection-locking signal(s). For example, injection circuit 170 (FIG. 1B) may be used to convert edges in refclk 114 into bipolar or unipolar pulses. This is illustrated in FIG. 3, which presents a timing diagram illustrating an embodiment 300 of clock signals and pulse waveforms, including refclk 114 and refpulses 310. Note that any one of the refpulses 310 may be used in alternate embodiments. Also note that, because of the high-pass nature of capacitors 130, slow falling edges in refpulses 310 may be largely blocked from injecting into the oscillator 132 by coupling capacitors 130 (FIGS. 1A and 1B). This allows rising and falling edges of refclk 114 to inject into the oscillator 132 with substantially different strengths, allowing operation for even values of M.

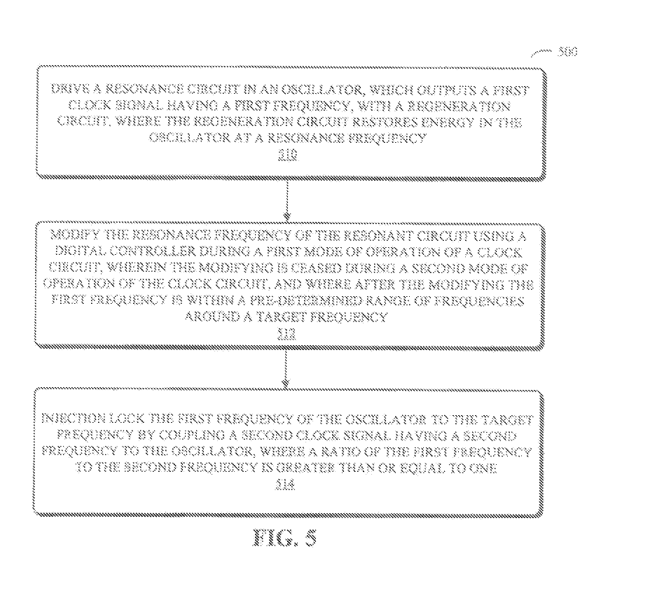

FIGS. 4A and 4B present block diagram illustrating embodiments of pulse-generating circuits 400 and 430 (such as injection circuit 170 in FIG. 1B). In pulse-generating circuit 400, inverters 414 and XOR gate 410 convert edges in refclk 114 into pulses in refpulse 310-4. Note that delays associated with either or both of the inverters 414 may be adjustable, and XOR gate 410 may have a fast rise time and a slow fall time (or a slow rise time and a fast fall time).

Similarly, in pulse-generating circuit 430 inverters 414 convert edges in refclk 114 into pulses in refpulse 310-5. Note that delays associated with either or both of the inverters 414 may be adjustable, and the inverters 414 may have a fast rise time and a slow fall time (or a slow rise time and a fast fall time).

In some embodiments, pulse-generating circuits 400 and/or 430 include fewer components or additional components. Furthermore, two or more components may be combined into a single component, and the position of one or more components may be changed.

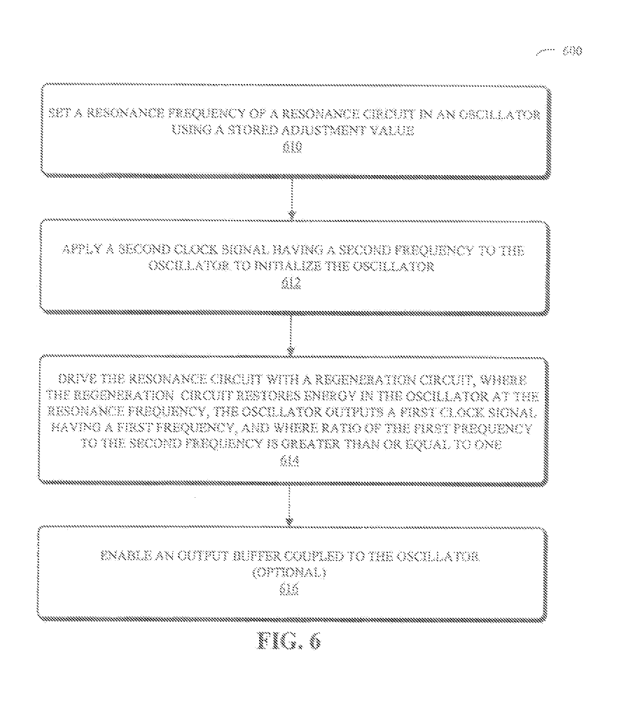

We now discuss embodiments of a process for generating clock signals. FIG. 5 presents a flow chart illustrating an embodiment of a process 500 for generating a clock signal using a digital controller and injection-locking circuit. During this process, a regeneration circuit drives a resonance circuit in the oscillator, which outputs a first clock signal having a first frequency (510). This regeneration circuit restores energy or compensate for energy loss in the oscillator at the resonance frequency. Furthermore, the digital controller modifies a resonance frequency of the oscillator (512) during a first or calibration mode of operation of a clock circuit. Note that after the modifying the first frequency is within a pre-determined range of frequencies around a target frequency, and the modifying is ceased during a second or active mode of operation of the clock circuit. Also note that the first mode of operation of the clock circuit may be an initialization or calibration mode, and the second mode may be an operating or active mode of operation.

Moreover, a second clock signal having a second frequency is coupled to the oscillator to injection lock the first frequency of the oscillator to the target frequency (514). Note that a ratio of the first frequency to the second frequency is greater than or equal to one.

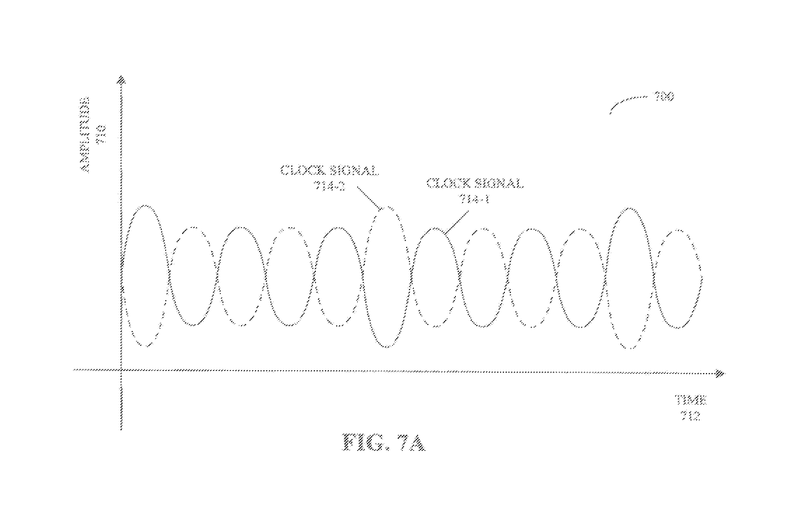

FIG. 6 presents a flow chart illustrating an embodiment of a process 600 for generating a clock signal using a stored resonance value. During this process, a resonance frequency of the resonance circuit in the oscillator is set based on the stored value (610). In addition, a second clock signal having a second frequency is applied to the oscillator to initialize the oscillator (612).

The regeneration circuit is used to drive the resonance circuit in the oscillator, which outputs a first clock signal having a first frequency (614). This regeneration circuit restores energy or compensate for energy loss in the oscillator at the resonance frequency. Furthermore, the ratio of the first frequency to the second frequency is greater than or equal to one. In some embodiments, an output buffer coupled to the oscillator is optionally enabled (616) (for example, using a control signal provided by control logic 150 in FIGS. 1A and 1B).

Note that in some embodiments there may be additional or fewer operations in processes 500 and/or 600. Furthermore, the order of the operations may be changed, and two or more operations may be combined into a single operation.

As noted previously, injection locking of the output clock signal(s) from the oscillator 132 (FIGS. 1A and 1B) may result in periodic jitter, which may be reduced or eliminated by band-pass filtering the output clock signal(s). This is illustrated in FIGS. 7A and 7B, which present graphs 700 and 730 (plotted as amplitude 710 versus time 712) illustrating embodiments of clock signals 714. Note the periodic modulation of clock signals 714-1 and 714-2 (such as clk 138 and clkb 140 in FIGS. 1A and 1B) in graph 700. After filtering, this modulation is reduced in clock signals 714-3 and 714-4 (such as clkdist 144 and clkdistb 146 in FIGS. 1A and 1B). Note that the periodic modulation of the clock signals 714-1 and 714-2 may include periodic amplitude and/or phase variations, although FIG. 7A predominantly illustrates a periodic-amplitude variation.

Referring back to FIGS. 1A and 1B, in an exemplary embodiment of the clock circuit 110 refclk 114 has a fundamental frequency of 1 GHz and clk 138 has a fundamental frequency of 5 GHz. A response of the clock circuit 110 to a 50 ps step in refclk 114 has a 1% setting time of approximately 5 ns. Furthermore, the locked/wake-up latency when transitioning from the standby mode of operation to the active mode of operation is approximately 6 ns. Note that clk 138 has a steady-state periodic jitter of 80 mUI (where UI is a unit interval equal to one-half of the period of clk 138). After filtering (for example, by the resonant-clock-distribution network 148), the period jitter is 25 mUI.

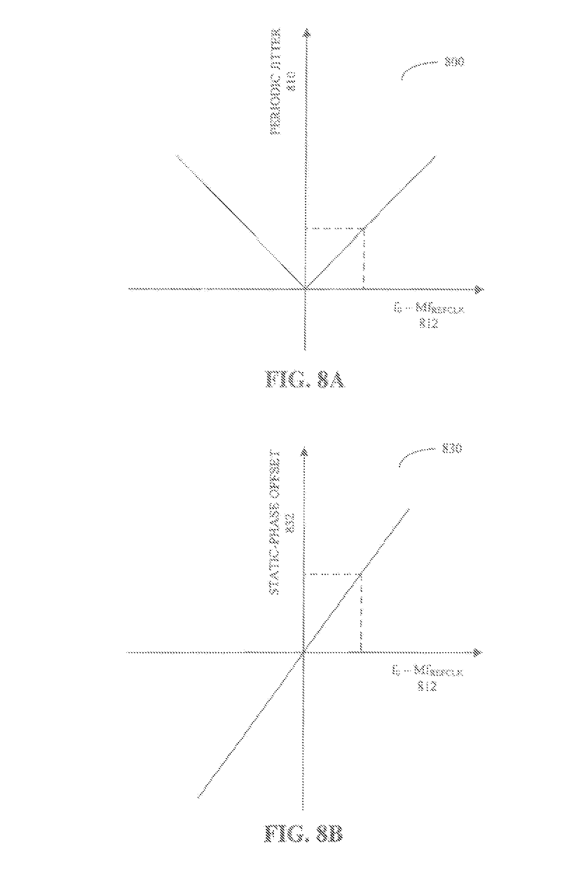

In some embodiments, the periodic jitter is further reduced or eliminated by measuring and correcting for a static-phase offset between refclk 114 and clk 138. This relationship is illustrated in FIGS. 8A and 8B, which present graphs 800 and 830 illustrating embodiments of periodic jitter 810 and static-phase offset 832 as a function of deviation from a target frequency 812 (where f₀ is the resonance frequency of oscillator 132 in FIGS. 1A and 1B, and Mf_{refclk} is the target frequency).

Referring back to FIGS. 1A and 1B, in some embodiments, after the frequency of the oscillator 132 has been locked during the active mode of operation, a phase comparator is used to adjust or reduce a static-phase offset. This may reduce or eliminate the periodic jitter associated with clk 138 and/or clkb 140. For example, in some embodiments the frequency/phase comparator 124 has two modes of operation. In the first mode of operation, frequency comparisons are performed (for example, during the calibration mode of operation of the clock circuit 110 in FIGS. 1A and 1B), and in the second mode of operation, phase comparisons are performed (for example, during the active mode of operation of the clock circuit 110 in FIGS. 1A and 1B).

During the second or active mode of operation, the static-phase offset may be measured and the resulting value of freq-ctrl 126 may be used to better match the ratio of the resonance frequency of oscillator 132 to the fundamental frequency of refclk 114. Thus, this technique uses the measured static-phase offset as a metric of the residual resonance frequency error. Note that the frequency/phase comparator 124 may include a zero phase detector to determine a zero static-phase offset value.

In addition, note that the static-phase-offset measurement or adjustment may be performed once, periodically, and/or as needed (for example, during the calibration mode of operation). Once determined, the frequency/phase comparator 124 may be disabled or may output a static value of freq-ctrl 126, thereby reducing power consumption in the active mode of operation. Also note that another frequency control setting (such as a digital word) corresponding to a value of freq-ctrl 126 for static-phase-offset correction may be stored and used to refine the setting of the resonance frequency of the oscillator 132 (for example, when switching from the standby mode of operation to the active mode of operation).

The foregoing descriptions of embodiments have been presented for purposes of illustration and description only. They are not intended to be exhaustive or to limit the present description to the forms disclosed. Accordingly, many modifications and variations will be apparent to practitioners skilled in the art. Additionally, the above disclosure is not intended to limit the present description. The scope of the present description is defined by the appended claims.

What is claimed is;

1. A clock circuit, comprising:
an oscillator, including a resonance circuit, having a resonance frequency, to output a first clock signal having a first frequency;
a digital controller, coupled to the oscillator, to modify the resonance frequency during a first mode of operation of the clock circuit and to cease the modifying during a second mode of operation of the clock circuit; and
an injection circuit, coupled to the oscillator, to provide a second clock signal having a second frequency to the oscillator to injection lock a phase and the first frequency of the first clock signal, wherein a ratio of the first frequency to the second frequency is greater than or equal to one.

2. The clock circuit of claim 1, wherein the ratio is an integer.

3. The clock circuit of claim 1, wherein the second clock signal includes pulses.

4. The clock circuit of claim 1, wherein the digital controller is to adjust the resonance frequency of the oscillator.

5. The clock circuit of claim 4, wherein the digital controller is to determine a frequency difference between a first signal corresponding to the first clock signal and a second signal corresponding to the second clock signal, and wherein the adjustment is based on the frequency difference.

6. The clock circuit of claim 4, wherein the digital controller is to determine a phase difference between a first signal corresponding to the first clock signal and a second signal corresponding to the second clock signal, and wherein the adjustment is based on the phase difference.

7. The clock circuit of claim 6, wherein the phase difference includes a static phase offset.

8. The clock circuit of claim 1, wherein the injection circuit is capacitively coupled to the oscillator.

9. The clock circuit of claim 8, wherein the capacitive coupling includes a capacitive divider.

10. The clock circuit of claim 1, further comprising an output buffer coupled to the oscillator.

11. The clock circuit of claim 1, wherein the oscillator is coupled to a filter.

12. The clock circuit of claim 11, wherein the filter includes a resonant-clock-distribution network.

13. The clock circuit of claim 1, further comprising a regeneration circuit coupled to the resonance circuit in the oscillator, wherein the regeneration circuit is to restore energy in the oscillator.

14. The clock circuit of claim 13, wherein the regeneration circuit is to have a negative transconductance.

15. The clock circuit of claim 13, wherein the clock circuit is to operate in a third mode of operation;
wherein during the third mode of operation the regeneration circuit, the digital controller, and the injection circuit are to be disabled; and
wherein when transitioning from the third mode of operation to the second mode of operation, the digital controller is enabled and is to set the resonance frequency based on a stored value, then the injection circuit and the regeneration circuit are enabled, and the injection circuit is to provide the second clock signal.

16. The clock circuit of claim 1, wherein the resonance circuit includes an inductor and a capacitor, and wherein the digital controller is to modify a capacitance of the capacitor.

17. The clock circuit of claim 1, wherein the injection circuit is an open-loop controller.

18. The clock circuit of claim 1, wherein the injection circuit is to receive a third clock signal;
wherein the second clock signal is based on the third clock signal; and
wherein the second clock signal is different than the third clock signal.

19. The clock circuit of claim 1, wherein the oscillator is to output a fourth clock signal having the first frequency;
wherein the fourth clock signal is out of phase with respect to the first clock signal;
wherein the injection circuit is to provide a fifth clock signal having the second frequency; and
wherein the fifth clock signal is out of phase with respect to the second clock signal.

20. A clock circuit, comprising:
an oscillator, including a resonance circuit having a resonance frequency, to output a first clock signal having a first frequency;
a digital controller, coupled, to the oscillator, to modify the resonance frequency during a first mode of operation of the clock circuit and to cease the modifying during a second mode of operation of the clock circuit; and
an injection circuit, coupled to the oscillator, including a pulse circuit to provide a second clock signal having a second frequency to the oscillator to injection lock a phase and the first frequency of the first clock signal, wherein the second clock signal includes pulses having a time spacing corresponding to the second frequency; and
wherein a ratio of the first frequency to the second frequency is greater than or equal to one.

21. An integrated circuit, comprising a clock circuit, wherein the clock circuit includes:
an oscillator, including a resonance circuit having a resonance frequency, to output a first clock signal having a first frequency;
a digital controller, coupled to the oscillator, to modify the resonance frequency during a first mode of operation of the clock circuit and to cease the modifying during a second mode of operation of the clock circuit; and
an injection circuit, coupled to the oscillator, to provide a second clock signal having a second frequency to the oscillator to injection lock a phase and the first frequency of the first clock signal, wherein a ratio of the first frequency to the second frequency is greater than or equal to one.

22. A clock circuit, comprising:
an oscillator, including a resonance circuit having a resonance frequency, to output a first clock signal having a first frequency;
a digital controller, coupled to the oscillator, to modify the resonance frequency during a first mode of operation of the clock circuit and to cease the modifying during a second mode of operation of the clock circuit; and
means for providing a second clock signal having a second frequency to the oscillator to injection lock a phase and the first frequency of the first clock signal, wherein a ratio of the first frequency to the second frequency is greater than or equal to one.

23. A method for generating a clock signal, comprising:
driving a resonance circuit in an oscillator, which outputs a first clock signal having a first frequency, with a regeneration circuit, wherein the regeneration circuit is to restore energy in the oscillator;
modifying a resonance frequency of the resonance circuit using a digital controller during a first mode of operation of the clock circuit, wherein the modifying is ceased during a second mode of operation of the clock circuit, and wherein after the modifying the first frequency is within a pre-determined range of frequencies around a target frequency; and
injection locking the first frequency of the oscillator to the target frequency by coupling a second clock signal having a second frequency to the oscillator, wherein a ratio of the first frequency to the second frequency is greater than or equal to one.
